(19) United States
(12) Patent Application Publication
(10) Pub. No.: US 2015/0365061 A1
(43) Pub. Date: Dec. 17, 2015

(54) SYSTEM AND METHOD FOR MODIFYING AN AUDIO SIGNAL

(71) Applicant: Hewlett-Packard Development Company, L.P., Houston, TX (US)

(72) Inventors: David Gough, Cypress, TX (US); Carlos O. Montalvo, Cupertino, CA (US)

(21) Appl. No.: 14/834,368

(22) Filed: Aug. 24, 2015

Related U.S. Application Data
(63) Continuation of application No. 13/259,441, filed on Sep. 23, 2011, now abandoned.

(51) Int. Cl. H03G 5/16; H03F 3/181

(52) U.S. Cl. CPC H03G 5/165; H03F 3/181

(57) ABSTRACT

A method and system for modifying an audio signal are provided. An audio subsystem can receive a control input signal including a predefined set of desired audio characteristics for an acoustic output of the audio subsystem. The audio subsystem can further receive an input audio electrical signal, and based on the control input signal, the audio subsystem can equalize, compress, limit and amplify the input audio electrical signal for output to at least one output device.

### CROSS REFERENCE TO RELATED APPLICATION

This Application is a Continuation of U.S. patent application Ser. No. 13/259,441, entitled “SYSTEM AND METHOD FOR MODIFYING AN AUDIO SIGNAL,” which is incorporated herein by reference in its entirety.

### BACKGROUND

Many contemporary electronic devices are designed to reproduce music and/or other audio signals. These electronic devices, such as, for example, personal computers, laptops, portable audio players, cell phones, etc., typically have integral speakers that convert electrical signals representing the audio information into sound for presentation to a listener/user. Such electronic devices are also typically configured to interconnect with external speakers and/or headphones. Speakers used to produce audio output each have unique electrical characteristics that influence the sound that they produce. Examples of these characteristics include frequency response, sensitivity, resonant frequency, damping factor, compliance and the like.

In addition, audio subsystems of electronic devices each have their own set of electrical characteristics and parameters, including, for example, total harmonic distortion, dither, noise floor, output power, and the like, that affect the processing of the audio electrical signals. Because of these unique characteristics, different electronic devices will process the same electrical audio signal differently. Because of differences in speakers and audio subsystems, the end result is that the same electrical audio signal will sound differently when processed by different audio subsystems and/or electronic devices.

### BRIEF DESCRIPTION OF THE DRAWINGS

Certain exemplary embodiments are described in the following detailed description and in reference to the drawings, in which:

FIG. 1 is a block diagram of an audio subsystem of an electronic device according to an exemplary embodiment of the present invention; and

FIG. 2 is a process flow diagram showing a method for modifying an audio signal to possess desired audio characteristics according to an exemplary embodiment of the present invention.

### DETAILED DESCRIPTION

Exemplary embodiments of the present invention relate to systems and methods that compensate for and/or take into consideration the electrical characteristics of the audio subsystem and/or speakers when converting electrical audio signals to audible sound. Moreover, exemplary embodiments relate to providing reproduced sound with improved fidelity and/or other desired characteristics. According to an exemplary embodiment of the present invention, it is also desirable to take into consideration factors that affect the characteristics of the recorded audio signals when making a sound recording. In this manner, it may be possible to improve the fidelity of reproduced audio signals when they are reproduced.

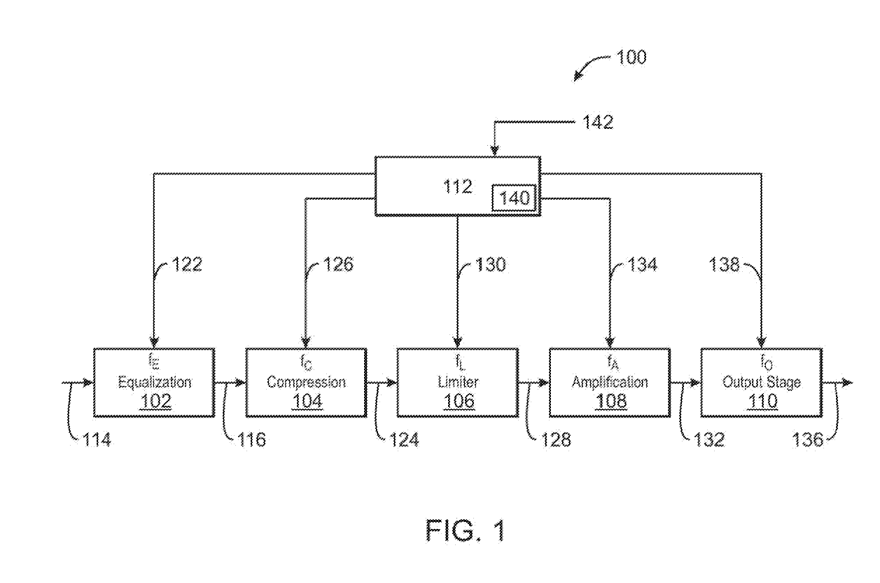

Referring now to the drawings and particularly to FIG. 1, there is shown a block diagram of an exemplary embodiment of an electronic device having an audio subsystem for optimizing the fidelity of reproduced sound. An electronic device includes an audio subsystem 100 which, in turn, includes a plurality of audio processing stages. More particularly, the audio processing stages of electronic device include an equalization stage 102, a compression stage 104, a limiter stage 106, an amplification stage 108 and an output stage 110. The electronic device further includes a processor or controller 112, which may be part of, integral with or separate from the audio subsystem 100.

Those of ordinary skill in the art will appreciate that the functional blocks and devices shown in the figures are only one example of functional blocks and devices that may be implemented in an exemplary embodiment of the present invention. Moreover, other specific implementations containing different functional blocks may be chosen based on system design considerations.

The equalization stage (EQ stage) 102 performs the process of altering, using passive or active electronic elements or digital algorithms, frequency response characteristics of audio subsystem 100. More particularly, one or more input audio electrical signals 114, such as, for example, analog or digital electrical signals, are received and processed by EQ stage 102. Equalized audio signals 116, such as, for example, analog or digital signals, are output by the EQ stage 102. The EQ stage 102 includes equalization stage control inputs 122. The operation of EQ stage 102 and its processing of input audio electrical signals 114 are dependent at least in part upon the equalization stage control inputs 122. More particularly, dependent at least in part upon the equalization stage control inputs 122, the EQ stage 102 alters the frequency response characteristics of audio subsystem 100. The equalization stage control inputs 122 may be, for example, digital or analog signals or other types of inputs.

The compression stage 104 receives and performs the process of compressing, using passive or active electronic elements or digital algorithms, equalized audio signals 116. Compressed audio signals 124, such as, for example, analog or digital signals, are produced as output by the compression stage 104. The compression stage 104 includes compression stage control inputs 126. The operation of the compression stage 104 and its processing of equalized audio signals 116 are dependent at least in part upon compression stage control inputs 126. More particularly, dependent at least in part upon compression stage control inputs 126, the compression stage 104 alters the compression characteristics of equalized audio signals 116 and, thus, of subsystem 100.

The limiter stage 106 receives and performs the process of limiting, using passive or active electronic elements or digital algorithms, compressed audio signals 124. Limited audio signals 128, such as, for example, analog or digital signals, are produced as output by the limiter stage 106. The limiter stage 106 includes limiter stage control inputs 130. The operation of the limiter stage 106 and its processing of compressed audio signals 124 are dependent at least in part upon limiter stage control inputs 130. More particularly, dependent at least in part upon the limiter stage control inputs 130, the limiter stage 106 alters the limiting characteristics of compressed audio signals 124 and, thus, of subsystem 100.

The amplification stage 108 receives and performs the process of amplifying, using passive or active electronic elements or digital algorithms, limited audio signals 128. Amplified audio signals 132, such as, for example, analog or digital signals, are produced as output by amplification stage 108. The amplification stage 108 includes amplification stage control inputs 134. The operation of the amplification stage 108 and its processing of limited audio signals 128 are dependent at least in part upon amplification stage control inputs 134. More particularly, dependent at least in part upon the amplification stage control inputs 134, the amplification stage 108 alters the amplitude characteristics of limited audio signals 128 and, thus, of subsystem 100.

The output stage 110 receives and performs the process of interfacing, using passive or active electronic elements or digital algorithms, amplified audio signals 132 to one or more output devices, such as, for example, electroacoustical transducers, output connectors, or subsequent circuitry. Output audio signals 136, such as, for example, analog or digital signals, are produced as output by the output stage 110. The output stage 110 includes output stage control inputs 138. The operation of the output stage 110 and its processing of amplified audio signals 132 are dependent at least in part upon the output stage control inputs 138.

The controller 112 is electrically connected with each of the EQ stage 102, the compression stage 104, the limiter stage 106, the amplification stage 108 and the output stage 110 and issues corresponding the stage control inputs 122, 126, 130, 134 and 138, respectively, to each. The controller 112, such as, for example, a microprocessor, executes control software 140 and receives one or more control input signals 142, each of which are more particularly described hereinafter.

In use, the audio subsystem 100 processes input audio signals 114 to produce output audio signals 136 having desired characteristics and, thus, a desired sound. The equalization stage 102 applies, dependent at least in part upon the equalization stage control inputs 122, a desired equalization or transfer function f_{E}, such as, for example, one or more of an amplitude, a phase, a time-delay, and a spatial directivity equalization, to audio signals 114 in order to produce the equalized audio signals 116.

The compression stage 104 applies, dependent at least in part upon the compression stage control inputs 126, a desired compression characteristic or transfer function f_{C}, such as, for example, variable gain, to the equalized audio signals 116 to produce the compressed audio signals 124. Generally, the desired compression characteristic or transfer function f_{C} applied by the compression stage 104 depends at least in part upon the level of the input equalized audio signals 116. For example, dependent at least in part upon the desired compression characteristic, the compression stage 104 may reduce the amount of gain applied when the input signal level is high, thereby making louder passages softer and reducing (or compressing) the dynamic range of the compressed audio signals 124. Conversely, dependent at least in part upon the desired compression characteristic, the compression stage 104 may increase the amount of gain when the input signal level is lower, thereby making softer passages louder and effectively increasing the dynamic range of the compressed audio signals 124.

The limiter stage 106 applies, dependent at least in part upon the limiter stage control signals 130, a desired limiter characteristic or transfer function f_{L}, such as, for example, a predetermined threshold level, to the compressed audio signal 124 to thereby produce the limited audio signals 128. Whereas the compression stage 104 will gradually and smoothly reduce the amount of gain applied above a desired compression threshold, the limiter stage 106 will substantially prevent additional gain being applied above a desired limiter threshold. Thus, the limiter stage 106 acts to block or remove signal peaks from the limited audio signals 128 which, if not blocked or removed, may result in the limited audio signal 128 having too high a level, e.g., being too loud or distorted.

The amplification stage 108 applies, dependent at least in part upon the amplification stage control inputs 134, a desired amplification characteristic or transfer function f_{A}, such as, for example, increasing the level of limited audio signals 128, to produce the amplified audio signals 132.

The output stage 110 applies, dependent at least in part upon the output stage control inputs 138, a desired output stage characteristic fₒ, such as, for example, buffers or otherwise processes, the amplified audio signals 132 to produce the output audio signals 136. The output audio signals 136, such as, for example, analog or digital signals, are produced as output by output stage 110.

Each of the audio processing stages of audio subsystem 100, i.e., the EQ stage 102, the compression stage 104, the limiter stage 106, the amplification stage 108 and the output stage 110, applies a respective processing characteristic or transfer function (f_{E}, f_{C}, f_{L}, f_{A}, f_{O}) to their respective input signals dependent at least in part upon their respective control inputs, i.e., the EQ stage control inputs 122, the compression stage control inputs 126, the limiter stage control signals 130, the amplification stage control inputs 134 and the output stage control inputs 138, to thereby produce their respective output signals.

Each of the stage control inputs 122, 126, 130, 134 and 138 are in the form of one or more electrical signals, such as, for example, analog, digital, or other electrical signals, generated by the controller 112 executing control software 140. The control software 140, dependent at least in part upon one or more control input signals 142 determines, such as, for example, calculates, derives or retrieves from a look-up table disposed in on-board or off-board memory, the appropriate transfer functions f_{E}, f_{C}, f_{L}, f_{A}, and f_{O} to be applied in order to produce audio output signals 136 having certain desired characteristics. The control input signal 142 may be predefined to thereby enable selection of a predefined set of desired audio characteristics and, thus, transfer functions or may be variable to provide the application of customized desired audio characteristics and, thus, transfer functions.

The transfer functions f_{E}, f_{C}, f_{L}, f_{A}, and f_{O} to be applied are dependent at least in part upon several considerations including, for example, the characteristics of the audio signal path (not shown) that lies beyond output stage 110 to which audio output signals 136 are directed (including the electroacoustical transducer or speaker and its characteristics), the preferred sound characteristics of one or more end listeners or groups of end listeners, the preferred sound characteristics of the recording and/or performing artists, and the characteristics of the environment in which the audio output signals 136 are to be reproduced.

In the exemplary embodiment described, the equalization stage 102, the compression stage 104, the limiter stage 106 and the amplification stage 108 are shown as sequential and separate stages. However, it is to be understood that exemplary embodiments of the present invention are not limited to the sequence of stages shown but rather can be alternately configured with the equalization stage 102, the compression stage 104, the limiter stage 106 and the amplification stage 108 operating in one or more different and various orders or sequences. Further, it is to be understood that exemplary embodiments of the present invention can be alternately configured, such as, for example, with the equalization stage 102, the compression stage 104, the limiter stage 106 and the amplification stage 108 being integrated into a single functional unit, such as a digital signal processing (DSP) application specific integrated circuit (ASIC).

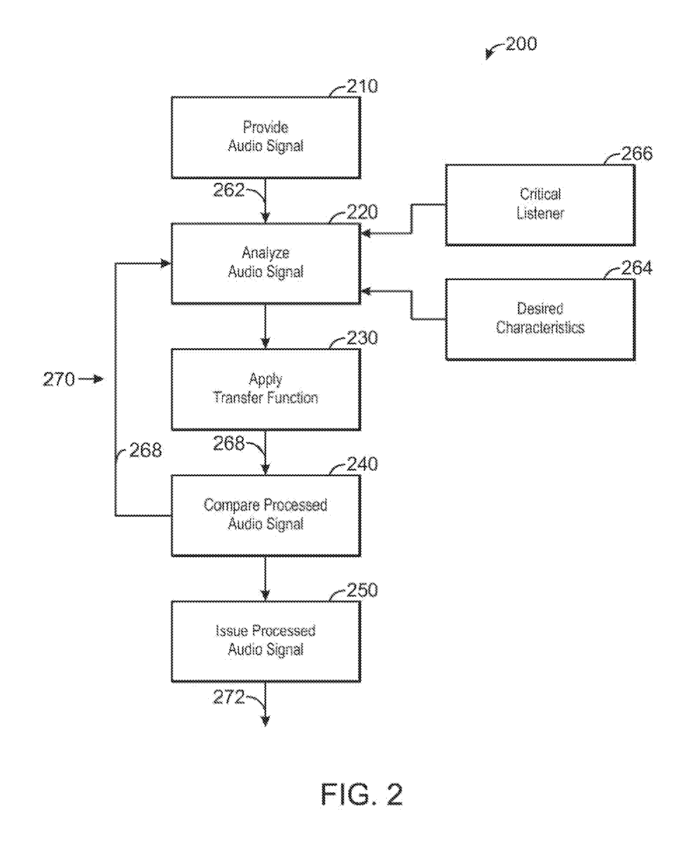

Referring now to FIG. 2, there is shown a method 200 for applying desired characteristics to an audio signal during recording and/or playback according to an exemplary embodiment of the present invention. The method 200 includes the processes of providing audio signals (block 210), analyzing an audio signal (block 220), applying the transfer function (block 230), comparing processed audio signals (block 240) and issuing a processed audio signal (block 250).

Providing audio signals, as shown at block 210, may include providing audio signals 262 according to the method 200. The audio signals 262 are, for example, previously-recorded electrical audio signals or, alternatively, audible sounds that are converted to audio signals that are provided as audio signals 262.

The process of analyzing audio signals (block 220) includes comparing one or more predetermined or selected characteristics of the provided audio signals 262 to corresponding one or more of the predetermined desired audio characteristics 264. The predetermined desired audio characteristics 264 and the predetermined characteristics of provided audio signals 262 may include, for example, one or more of an output level, an amplitude, a dynamic range, a frequency content, an amount of compression, a harmonic distortion and other characteristics. The process of analyzing audio signals (block 220) determines, at least in part, the transfer function to be applied to audio signals 262 by applying the transfer function (block 230).

In one exemplary embodiment of the present invention, the process of analyzing audio signals (block 220) is performed electronically, such as, for example, by a processor executing one or more software-based instructions or algorithms that compares the predetermined characteristics of the provided audio signals 262 with the corresponding predetermined desired characteristics 264. Alternatively, in another exemplary embodiment of the present invention, the process of analyzing audio signals (block 220) includes listening to an audible reproduction of provided audio signals 262 for the degree, presence, or absence of the predetermined desired characteristics 264. The listening is done by a critical listener 266, such as, for example, a so-called golden ear, the artist who performed the music corresponding to the audio signals, a producer, or sample listener group.

Applying the transfer function (block 230) includes applying an appropriate transfer function to modify one or more of the predetermined characteristics of the provided audio signals 262 to produce a modified or processed audio signal 268 wherein one or more of the predetermined characteristics of provided audio signals 262 has been modified to more closely approximate a corresponding one or more of the predetermined desired audio characteristics 264.

Comparing processed audio signals (block 240) may include comparing one or more predetermined characteristics of the processed audio signal 268 to the corresponding predetermined desired audio characteristics 264. Comparing processed audio signals (block 240) may be performed electronically, such as, for example, by a processor executing one or more software-based instructions or algorithms that compares the one or more predetermined characteristics of the processed audio signal 268 with one or more corresponding predetermined desired characteristics 264. Alternatively, in another exemplary embodiment of the present invention, the process of analyzing audio signals (block 220) includes listening to an audible reproduction of the processed audio signals 268 for the degree, presence, or absence of one or more of predetermined desired characteristics 264. The listening may also be done by a critical listener 276, such as, for example, a so-called golden ear, the artist who performed the music corresponding to the audio signals, or a producer, which may be the same listener, or a different listener than, the critical listener 266.

Dependent at least in part upon comparing the processed audio signal 240, the processes of analyzing audio signal (block 220), applying the transfer function (block 230) and comparing process (block 240) are either repeated or an output audio signal is issued.

More particularly, as is shown by a loop 270, if the result of comparing processed audio signal (block 240) indicates one or more of the predetermined characteristics of the processed audio signal 268 does not match closely enough, such as, for example, within a predetermined tolerance, the corresponding one or more predetermined desired audio characteristics 264, the processed audio signal 268 is again directed by the method 200 through the processes of analyzing the audio signal (block 220), applying the transfer function (block 230) and comparing (block 240). The processing of processed audio signal 268 continues in this iterative manner until the result of comparing processed audio signal (block 240) indicates the predetermined characteristics of the processed audio signal 268 match, such as, for example, within a predetermined tolerance, the corresponding one or more predetermined desired audio characteristics 264.

At block 250, the processed audio signal 268 is issued for an intended use, such as, for example, reproduction via an electroacoustical transducer such as a speaker, recording to a tangible or intangible medium, further processing, transmission, or the like.

The distinction between the processes of analyzing audio signal (block 220) and comparing processed audio signal (block 240) is that the former process (i.e., analyzing audio signal process (block 220)) involves determining an appropriate transfer function to be applied. Conversely, the comparing process (block 240) determines, either by electronic/software analysis or audible monitoring by a critical listener, whether the processed audio signal 268 approximates to a predetermined and satisfactory degree one or more predetermined desired audio characteristics 264 and, thus, whether or not additional processing steps are needed.

By contrast, the process of analyzing audio signals (block 220) determines, also based on either electronic/software analysis or analysis by a critical listener, which of the predetermined audio characteristics are in need of modification, such as, for example, emphasis or de-emphasis, in order to match within a specified degree the desired audio characteristics 264.

Exemplary embodiments of the present invention may provide distinct advantages. The method 200 enables the recording and/or reproduction of the processed audio signals 268 having a distinct, characteristics and/or unique sound regardless of the various parameters of, and factors that affect, the recording and/or reproduction process. By taking into consideration the various parameters of, and factors that affect, the recording and/or reproduction process, the method 200 enables the recording and/or reproduction of the processed audio signals 268 having distinct, characteristics and/or unique sound. For example, the audio signals 268 may be processed to compensate for the electrical and/or acoustic characteristics of a particular electroacoustic transducer or speaker to be used in reproducing audio signals 268, in order to counteract and, thereby, preserve and ensure the distinct, characteristics and/or unique sound is faithfully reproduced.

What is claimed is:

1. An audio subsystem comprising:
a controller to execute control software, causing the audio subsystem to:
receive a control input signal comprising a predefined set of desired audio characteristics for an acoustic output of the audio subsystem;
receive an input audio electrical signal;
based on the control input signal, (i) equalize the input audio electrical signal, (ii) compress the input audio electrical signal, (iii) limit the input audio electrical signal, and (iv) amplify the input audio electrical signal; and
output the equalized, compressed, limited, and amplified input audio electrical signal to at least one output device.

2. The audio subsystem of claim 1, wherein equalizing the input audio electrical signal comprises altering at least one of an amplitude, a phase, a time-delay, or a spatial directivity equalization of the input audio electrical signal based on the control input signal.

3. The audio subsystem of claim 2, wherein compressing the input audio electrical signal comprises altering at least one of an amount of gain or a dynamic range of the equalized input audio electrical signal based on the control input signal.

4. The audio subsystem of claim 3, wherein limiting the input audio electrical signal comprises preventing additional gain from being applied to the equalized and compressed input audio electrical signal above a desired limiter threshold, the desired limiter threshold being defined based on the control input signal.

5. The audio subsystem of claim 4, wherein limiting the input audio electrical signal further comprises at least one of blocking or removing signal peaks from the equalized and compressed input audio electrical signal based on the desired limiter threshold.

6. The audio subsystem of claim 4, wherein amplifying the input audio electrical signal comprises increasing an output level of the equalized, compressed, and limited input audio electrical signal based on the control input signal.

7. The audio subsystem of claim 1, wherein the predefined set of desired audio characteristics comprises at least one of a preconfigured output level, amplitude, dynamic range, frequency content, amount of compression, or harmonic distortion.

8. The audio subsystem of claim 6, wherein the predefined set of desired audio characteristics is preconfigured by a critical listener of audio corresponding to the input audio electrical signal.

9. The audio subsystem of claim 1, wherein the input audio electrical signal corresponds to music.

10. The audio subsystem of claim 1, wherein the at least one output device comprises at least one of electroacoustical transducers, output connectors, speakers, or headphones.

11. The audio subsystem of claim 1, wherein equalizing, compressing, limiting, and amplifying the input audio electrical signal comprises applying a number of transfer functions to the input audio electrical signal based on the control input signal.

12. The audio subsystem of claim 1, wherein equalizing, compressing, limiting, and amplifying the input audio electrical signal comprises applying specified transfer functions to the input audio electrical signal for each of the equalizing, compressing, limiting, and amplifying of the input audio electrical signal.

13. The audio subsystem of claim 12, wherein the executed control software causes the controller to select the specified transfer functions for each of the equalizing, compressing, limiting, and amplifying of the input audio electrical signal based on the predefined set of desired audio characteristics.

14. An electronic device comprising:
at least one output device; and
a controller to execute control software, causing the electronic device to:
receive a control input signal comprising a predefined set of desired audio characteristics for an acoustic output of the electronic device;
receive an input audio electrical signal;
based on the control input signal, (i) equalize the input audio electrical signal, (ii) compress the input audio electrical signal, (iii) limit the input audio electrical signal, and (iv) amplify the input audio electrical signal; and
output the equalized, compressed, limited, and amplified input audio electrical signal to the at least one output device.

15. A method of compensating for electrical characteristics of an audio subsystem comprising:
receiving a control input signal comprising a predefined set of desired audio characteristics for an acoustic output of the audio subsystem;
receive an input audio electrical signal;
based on the control input signal, (i) equalize the input audio electrical signal, (ii) compress the input audio electrical signal, (iii) limit the input audio electrical signal, and (iv) amplify the input audio electrical signal; and
output the equalized, compressed, limited, and amplified input audio electrical signal to at least one output device.
